(19) United States
(12) Patent Application Publication
(10) Pub. No.: US 2026/0136973 A1
(43) Pub. Date: May 14, 2026

(54) INTERPOSER, SEMICONDUCTOR PACKAGE INCLUDING THE SAME AND METHOD FOR MANUFACTURING THE SAME

(71) Applicant: Samsung Electronics Co., Ltd., Suwon-si (KR)

(72) Inventors: YUKYUNG PARK, Suwon-si (KR); Hyeonjae Kim, Suwon-si (KR); SEUNG-KWAN RYU, Suwon-si (KR)

(21) Appl. No.: 19/248,960

(22) Filed: Jun. 25, 2025

(30) Foreign Application Priority Data
Nov. 8, 2024 (KR) 10-2024-0158407

(51) Int. Cl. H01L 23/498; H01L 21/48; H01L 23/00; H01L 23/538; H01L 25/18; H10B 80/00; H10D 80/30

(52) U.S. Cl. CPC H10W 70/685; H10W 70/05; H10W 70/093; H10W 70/095; H10W 70/611; H10W 70/65; H10W 70/69; H10W 90/00; H10W 90/701; H10B 80/00; H10D 80/30; H10W 90/724

(57) ABSTRACT

An embodiment of the present disclosure provides an interposer including: a base layer including a front side and a back side which is opposite to the front side; a wiring layer at the front side; a passivation layer at the back side, the passivation layer including a first surface contacting the back side and a second surface opposite to the first surface, the second surface including a recessed portion; one or more through silicon vias electrically connected to the wiring layer, the one or more through silicon vias extending through the base layer and the passivation layer, the one or more through silicon vias protruding from the recessed portion; and a conductive pillar disposed on the recessed portion and covering a surface of the one or more through silicon vias.

### CROSS-REFERENCE TO RELATED APPLICATION

This application claims priority under 35 U.S.C. § 119 to and the benefit of Korean Patent Application No. 10-2024-0158407, filed in the Korean Intellectual Property Office on Nov. 8, 2024, the entire contents of which are incorporated herein by reference.

### BACKGROUND OF THE DISCLOSURE

### (a) Field of the Disclosure

The present disclosure relates to an interposer, a semiconductor package including the interposer, and a manufacturing method for the interposer.

### (b) Description of the Related Art

As miniaturization and higher performance are required for semiconductor chips, a demand for semiconductor chips with increased number and density of I/O terminals is increasing. To route power or signals between semiconductor chips, packaging is required to connect semiconductor chips to a substrate. However, it is difficult to directly connect semiconductor chips with an increased number and density of I/O terminals to a substrate with a relatively small number and low density of I/O terminals, so an interposer with an intermediate number and density of I/O terminals has been developed as an intermediate medium between the semiconductor chips and the substrate, and is being used to connect the semiconductor chips and the substrate.

Interposers involve high-temperature processes during their manufacturing process, and warpage may occur in the interposers during the high-temperature processes. In the past, in order to prevent warpage in an interposer, a redistribution pad was formed in a passivation layer on a back side of a base layer of the interposer according to a metal ratio in a wiring layer on a front side of the base layer of the interposer, but there were problems such as many additional processes had to be performed to form the redistribution pad, equipment infrastructure was required for this, and the turn around time (TAT) increased.

In addition, the redistribution pad may be formed by performing a wet etching process on exposed surfaces of through silicon vias (TSV) to form an engraved via, and performing a photolithography process using the engraved via as an alignment key. However, due to a nature of wet etching, it is difficult to control roughness of an engraved via, and thus there is a problem in measuring the engraved via.

### SUMMARY OF THE DISCLOSURE

Embodiments of the present disclosure provide an interposer and a semiconductor package including the interposer, in which through silicon vias (TSV) and conductive pillars are directly connected within a passivation layer on a back side of a base layer.

An embodiment of the present disclosure provides an interposer including: a base layer including a front side and a back side which is opposite to the front side; a wiring layer on the front side; a passivation layer on the back side, the passivation layer including a first surface contacting the back side and a second surface opposite to the first surface, the second surface including a recessed portion; one or more through silicon vias electrically connected to the wiring layer, the one or more through silicon vias extending through the base layer and the passivation layer, the one or more through silicon vias protruding from the recessed portion; and a conductive pillar disposed on the recessed portion and covering a surface of the one or more through silicon vias.

An embodiment of the present disclosure provides an interposer including: a base layer including a front side and a back side which is opposite to the front side; a wiring layer on the front side; a passivation layer on the back side, the passivation layer including a first surface contacting the back side and a second surface opposite to the first surface, the second surface including a first region having a first thickness in a direction perpendicular to the first surface and a plurality of second regions having a second thickness in a direction perpendicular to the first surface, the second thickness being less than the first thickness; a plurality of through silicon vias electrically connected to the wiring layer; and a plurality of conductive pillars on a second surface of the passivation layer, wherein each of the plurality of through silicon vias includes: a first portion extending through the base layer and a corresponding second region among the plurality of second regions; and a second portion protruding from the corresponding second region; and wherein each conductive pillar of the plurality of conductive pillars covers the second portion of a corresponding through silicon via of the plurality of through silicon vias.

An embodiment of the present disclosure provides a semiconductor package including: a substrate; and an interposer on the substrate; a logic die on the interposer; and a memory die on the interposer and next to the logic die, wherein the interposer includes: a base layer including a front side and a back side which is opposite to the front side; a wiring layer on the front side; a plurality of bonding pads disposed on the wiring layer, each bonding pad electrically connected to the logic die or the memory die; a passivation layer disposed on the back side and including a first surface contacting the back side, and a second surface opposite to the first surface and including a plurality of recessed portions; a plurality of through silicon vias electrically connected to the wiring layer, the plurality of through silicon vias extending through the base layer and the passivation layer, the plurality of through silicon vias protruding from the recessed portions; and a plurality of conductive pillars, each of the plurality of conductive pillars disposed on a corresponding recessed portion among the recessed portions, each of the plurality of conductive pillars covering a protruding surface of a corresponding through-silicon via among the plurality of through-silicon vias.

The redistribution pad is not included within the passivation layer on the back side of the base layer according to some embodiments of the present disclosure, so an additional process for forming the redistribution pad may not be performed, thereby reducing the turn around time (TAT) required.

Due to the shape of the through silicon via (TSV) protruding from the recessed portion of the passivation layer, anchoring between the through silicon via (TSV) and the conductive pillar may be improved, and an area of the under bump metallurgy (UBM) layer interposed between the through silicon via (TSV) and the conductive pillar may be increased. This may improve reliability of the electrical connection between the through silicon via (TSV) and the conductive pillar.

A photolithography process may be performed to form conductive pillars using easily measurable protruding through-silicon vias (TSVs) as alignment keys.

### BRIEF DESCRIPTION OF THE DRAWINGS

FIG. 1 illustrates a cross-sectional view showing an interposer according to an embodiment.

FIG. 2 illustrates an enlarged cross-sectional view showing a region A of the interposer of FIG. 1.

FIG. 3 illustrates a cross-sectional view showing a modified embodiment of the interposer of FIG. 1 and a region A of FIG. 2.

FIG. 4 illustrates a cross-sectional view showing a modified embodiment of the interposer of FIG. 1 and a region A of FIG. 2.

FIG. 5 illustrates a cross-sectional view showing a modified embodiment of the interposer of FIG. 1 and a region A of FIG. 2.

FIG. 6 illustrates a cross-sectional view showing a modified embodiment of the interposer of FIG. 1 and a region A of FIG. 2.

FIG. 7 illustrates a cross-sectional view showing a modified embodiment of the interposer of FIG. 1 and a region A of FIG. 2.

FIG. 8 illustrates a cross-sectional view showing a semiconductor package including the interposer of FIG. 1.

FIG. 9 to FIG. 23 illustrate cross-sectional views for describing a manufacturing method for the interposer of FIG. 1.

### DETAILED DESCRIPTION OF THE EMBODIMENTS

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

To clearly describe the present disclosure, parts that are not closely relevant to focused features of the description in the drawings may be omitted, and like numerals refer to like or similar constituent elements throughout the specification.

Further, since sizes and thicknesses of constituent members shown in the accompanying drawings may be exaggerated and may not reflect exact proportions for better understanding and ease of description, the present inventive concept is not limited to the illustrated sizes and thicknesses.

Throughout this specification and the claims that follow, when it is described that an element is “coupled/connected” to another element, the element may be “directly coupled/connected” to the other element or “indirectly coupled/connected” to the other element through a third element, e.g., intervening elements may be present. In contrast, when an element is referred to as being “directly connected” or “directly coupled” to another element, or as “contacting” or “in contact with” another element (or using any form of the word “contact”), there are no intervening elements present at the point of contact.

Unless explicitly described to the contrary, the word “comprise” and variations such as “comprises” or “comprising” will be understood to imply the inclusion of stated elements but not the exclusion of any other elements.

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction. For example, spatially relative terms, such as “beneath,” “below,” “lower,” “above,” “upper,” “top,” “bottom,” “front,” “rear,” and the like, may be used herein for ease of description to describe positional relationships, such as illustrated in the figures, for example. It will be understood that the spatially relative terms encompass different orientations of the device in addition to the orientation depicted in the figures.

As used herein, components described as being “electrically connected” are configured such that an electrical signal can be transferred from one component to the other (although such electrical signal may be attenuated in strength as it is transferred and may be selectively transferred).

Various pads of a device described herein may be conductive terminals connected to internal wiring of the device, and may transmit signals and/or supply voltages between an internal wiring and/or internal circuit of the device and an external source. For example, chip pads of a semiconductor chip may electrically connect to and transmit supply voltages and/or signals between an integrated circuit of the semiconductor chip and a device to which the semiconductor chip is connected. The various pads may be provided on or near an external surface of the device and may have a planar surface having dimensions greater than wiring (e.g., X-Y horizontal dimensions of a pad are both greater than the width of an internal writing to which it is connected) to promote an electrical connection to a further terminal, such as a bump or solder ball, and/or an external wiring.

Further, throughout the specification, the phrase “in a plan view” means when an object portion is viewed from above, and the phrase “in a cross-sectional view” means when a cross-section taken by vertically cutting an object portion is viewed from the side.

Hereinafter, an interposer 100 of an embodiment, a semiconductor package 200 including the interposer 100, and a method manufacturing for the interposer 100 will be described with reference to the drawings.

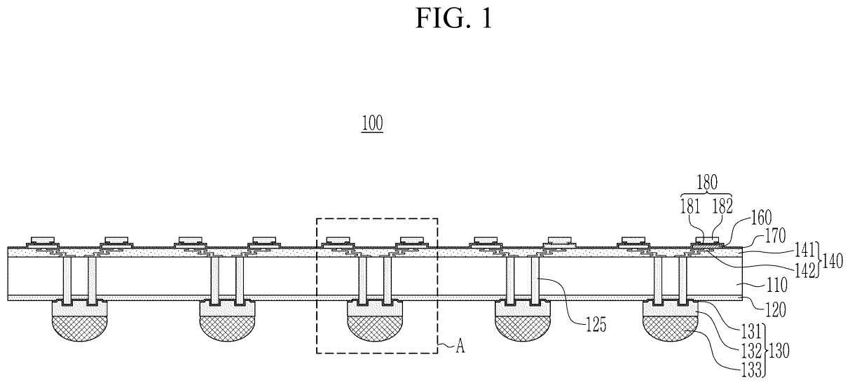

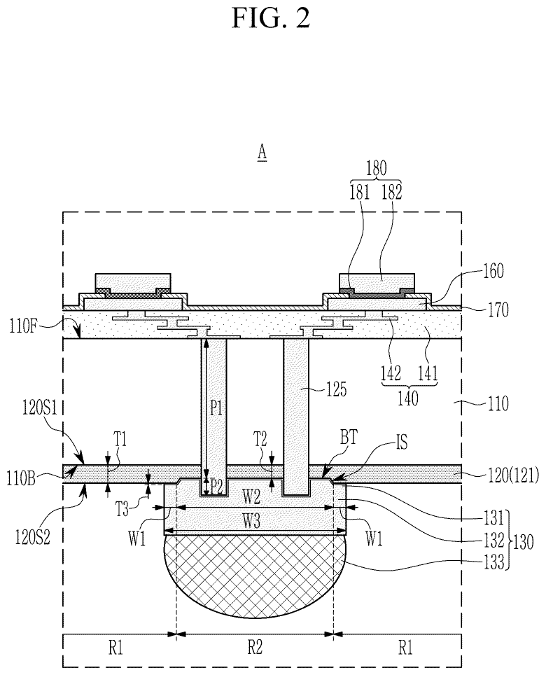

FIG. 1 illustrates a cross-sectional view showing the interposer 100 according to an embodiment. FIG. 2 illustrates an enlarged cross-sectional view showing a region A of the interposer 100 of FIG. 1.

Referring to FIGS. 1 and 2, the interposer 100 may include a base layer 110, a passivation layer 120, through silicon vias (TSV) 125, a bump structure 130, a wiring layer 140, wiring pads 160, a protection layer 170, and bonding pads 180. In an embodiment, the interposer 100 may include a silicon interposer, a glass interposer, an organic interposer, and a composite interposer. In an embodiment, the interposer 100 may be manufactured based on or to be compatible with fan out wafer level package (FOWLP) or fan out panel level package (FOPLP) technology.

The base layer 110 may include a front side (e.g., an active side) 110F and a back side (e.g., an inactive side) 110B opposite to the front side 110F. The base layer 110 may include silicon, glass, an organic dielectric material, or another semiconductor material. The base layer 110 may be a die formed from a wafer.

The passivation layer 120 may be disposed on the back side 110B of the base layer 110. The passivation layer 120 may include a first surface 120S1 that contacts the back side 110B of the base layer 110 and a second surface 120S2 that is opposite to the first surface 120S1 and includes a recessed portion. The passivation layer 120 may include a first region R1 and second regions R2. The first region R1 and the second regions R2 may divide the second surface 120S2 of the passivation layer 120. The first region R1 may be a non-recessed region. The first region R1 may have a first thickness T1 in a vertical direction, e.g., from the first surface 120S1 to the second surface 120S2. In an embodiment, the first thickness T1 may be in a range of about 2 μm to about 5 μm. The second regions R2 may be regions including recessed portions. The second regions R2 may have a second thickness T2 in the vertical direction, e.g., from the first surface 120S1 to the second surface 120S2. The second thickness T2 may be smaller than the first thickness T1. In an embodiment, the second thickness T2 may be in a range of about 1.5 μm to about 4.95 μm.

The recessed portion may include a bottom surface BT and an inner surface IS. The bottom surface BT of the recessed portion may be the uppermost surface of the recessed portion of the passivation layer 120. The inner surface IS may have a profile that is inclined at an angle with respect to the bottom surface BT, e.g., in a cross-sectional view. The inner surface IS of the recessed portion may be a side surface (e.g., a surface of the sidewall) of the recessed portion. In a case where the passivation layer 120 is an organic dielectric layer 121, a photolithography process may be performed to form a recessed portion, and in a process of exposing and developing the organic dielectric layer 121, an inner surface (IS) having a profile that is inclined with respect to the bottom surface BT may be formed. The recessed portion (or bottom surface BT) may have a second width W2 in a horizontal direction. In an embodiment, the second width W2 may be in a range of about 30 μm to about 100 μm.

The passivation layer 120 may include an organic dielectric layer 121. In an embodiment, the organic dielectric layer 121 may include a photoimageable dielectric (PID). The photoimageable dielectric (PID) may be a material capable of forming fine patterns by applying a photolithography process. In an embodiment, the photoimageable dielectric (PID) may include a polyimide-based photosensitive polymer (a photosensitive polymer made from and/or including polyimide), a novolak-based photosensitive polymer (e.g., a photosensitive polymer derived from phenol and formaldehyde condensation polymers), polybenzoxazole, a silicone-based polymer (a polymer including silicon atom), an acrylate-based polymer (e.g., a polymer derived from acrylate monomers), or an epoxy-based polymer (e.g., an epoxy resin).

The through-silicon vias 125 may be electrically connected to and/or contact the wiring layer 140, extend lengthwise through the base layer 110 and the second regions R2 of the passivation layer 120, e.g., in a vertical direction, and may protrude from the second surface 120S2 of the second regions R2. A first end of each of the through silicon vias 125 may be electrically connected to and/or contact a corresponding wiring pattern 142 of wiring patterns 142 of the wiring layer 140, and a second end opposite to the first end may be electrically connected to a corresponding conductive pillar 132 of conductive pillars 132 through an under bump metallurgy (UBM) layer. Each of the through silicon vias 125 may electrically connect a corresponding wiring pattern 142 among the wiring patterns 142 to a corresponding conductive pillar 132 among the conductive pillars 132. The number of through silicon vias 125 protruding from the second surface 120S2 of each of the second regions R2 may be one or more. A plurality of through silicon vias 125 protruding from the second surface 120S2 of each of the second regions R2 may be arranged for redundancy/backup. In an embodiment, the number of through silicon vias 125 protruding from the second surface 120S2 of each of the second regions R2 may be 1, 2, 4, or 6.

Each of the through silicon vias 125 may include a first portion P1 extending through the base layer 110 and the second regions R2 of the passivation layer 120, and a second portion P2 protruding from the second regions R2. A level of the second end of the through silicon via 125 protruding from each of the second regions R2 among the second regions R2 may be lower than a level of the second surface 120S2 in the second region R2. A vertical height of the second portion P2 may be greater than or equal to a difference between the first thickness T1 and the second thickness T2. The second portion P2 may be covered and surrounded by a conductive pillar 132.

The through silicon vias 125 may have a cylindrical or elliptical columnar shape. For example, each of the through silicon vias 125 may have a circular shape or an elliptical shape in a plan view. In an embodiment, the through silicon vias 125 may include at least one of tungsten, aluminum, copper, or an alloy thereof. A barrier layer may be formed around the through silicon vias 125. The barrier layer may serve to prevent silicon of the base layer 110 or dielectric of the passivation layer 120 from contacting the through-silicon via. In an embodiment, the barrier layer may include at least one of titanium, tantalum, a titanium nitride, a tantalum nitride, or an alloy thereof.

Bump structures 130 may be disposed on the passivation layer 120. Each of the bump structures 130 may include an under bump metallurgy (UBM) layer 131, a conductive pillar 132, and a solder 133.

The under bump metallurgy (UBM) layer 131 may be provided between the conductive pillar 132 and the second surface 120S2 of the second region R2 (recessed portion) of the passivation layer 120, between the conductive pillar 132 and a portion of the first region R1 around the second region R2 (recessed portion) of the passivation layer 120, and between surfaces of one or more through silicon vias 125 protruding from the second surface 120S of the second region R2 (recessed portion) of the passivation layer 120. The under bump metallurgy (UBM) layer 131 may extend continuously and conformally between the conductive pillar 132 and the second region R2 (recessed portion) of the passivation layer 120, between the conductive pillar 132 and a portion of the first region R1 around the second region R2 (recessed portion) of the passivation layer 120, and between surfaces of one or more through silicon vias 125 protruding from the second surface 120S2 of the second region R2 (recessed portion) of the passivation layer 120. The portion of the first region R1 around the second region R2 (recessed portion) where the under bump metallurgy (UBM) layer 131 extends may be a region having a first width W1 in the horizontal direction from an edge of the recessed portion. In an embodiment, the first width W1 may be in a range of about 1 μm to about 3 μm.

The under bump metallurgy (UBM) layer 131 may include a diffusion barrier layer and a seed metal layer. The diffusion barrier layer and the seed metal layer may line the space between the second surface 120S2 of the passivation layer 120 and the conductive pillar 132. For example, the diffusion barrier layer and the seed metal layer may be interposed between the second surface 120S2 of the passivation layer 120 and the conductive pillar 132. The diffusion barrier layer may improve electrical properties between the through silicon via 125 and the conductive pillar 132. The diffusion barrier layer may act as an adhesion layer. In an embodiment, the diffusion barrier layer may include at least one of a tantalum nitride, a titanium nitride, tantalum, titanium, and an alloy thereof. In an embodiment, the diffusion barrier layer may have a third thickness T3 in a range of about 50 nm to about 500 nm. The seed metal layer may be indistinguishable from the conductive pillar 132. For example, the seed metal layer and the conductive pillar 132 may be integrally formed as one body without boundaries therebetween. In an embodiment, the seed metal layer may have a thickness in a range of about 200 nm to about 800 nm. In an embodiment, the seed metal layer may be formed of a copper alloy, or copper including silver, chromium, nickel, tin, gold, and a combination thereof.

The conductive pillar 132 may be disposed on the passivation layer 120. The conductive pillar 132 may be disposed on an under bump metallurgy (UBM) layer 131. The conductive pillar 132 may be disposed on the second surface 120S2 of the second region R2 (recess portion) of the passivation layer 120. The conductive pillar 132 may cover or vertically overlap the second region R2 (recessed portion) of the passivation layer 120, and a portion of the first region R1 around the second region R2 (recessed portion) of the passivation layer 120. The portion of the first region R1 around the second region R2 (recessed portion) covered by the conductive pillar 132 may be a region having the first width W1 in the horizontal direction from an edge of the recessed portion. In an embodiment, the first width W1 may be in a range of about 1 μm to about 3 μm. The conductive pillar 132 may cover surfaces of one or more through hole silicon vias 125 protruding from the second face 120S2 of the second region R2 (recessed portion) of the passivation layer 120. The conductive pillar 132 may cover and surround the second portion P2 of the through silicon via 125. The conductive pillar 132 may have a third width W3 in the horizontal direction. The third width W3 of the conductive pillar 132 may be greater than the second width W2 of the second region R2 (recessed portion or bottom surface BT). In an embodiment, the third width W3 may be in a range of about 32 μm to about 106 μm. In an embodiment, the conductive pillar 132 may include copper. In an embodiment, a thickness of the conductive pillar 132 in the vertical direction may be in a range of about 30 μm to about 150 μm.

The solder 133 may be disposed on the conductive pillar 132, and may be electrically connected to and/or contact the conductive pillar 132. In an embodiment, the solder 133 may include at least one of tin, silver, lead, nickel, copper, or an alloy thereof.

The wiring layer 140 may be disposed on the front side 110F of the base layer 110. The wiring layer 140 may include an intermetal dielectric (IMD) 141 and the wiring patterns 142. The intermetal dielectric (IMD) 141 may protect and insulate the wiring patterns 142. In an embodiment, the intermetal dielectric (IMD) 141 may include SiO₂, SiOC, SiOH, SiOCH, TEOS, or a low-k dielectric layer. The wiring patterns 142 may be disposed within the intermetal dielectric (IMD) 141.

The wiring patterns 142 may include contact plugs and wiring lines. The contact plugs may form a vertical signal routing path that electrically connects a corresponding wiring pad 160 among the wiring pads 160 to a corresponding through silicon via 125 among the through silicon vias 125. For example, the contact plugs may extend lengthwise in a vertical direction. The wiring lines may form a horizontal signal routing path that electrically connects a corresponding wiring pad 160 among the wiring pads 160 to a corresponding through silicon via 125 among the through silicon vias 125. For example, the wiring lines may extend lengthwise in a horizontal direction. In an embodiment, the wiring patterns 142 may include at least one of copper, aluminum, tungsten, nickel, gold, tin, titanium, or an alloy thereof.

The wiring pads 160 may be disposed on the wiring layer 140. Each of the wiring pads 160 may be disposed between corresponding wiring patterns 142 among the wiring patterns 142 and corresponding bonding pads 180 among the bonding pads 180. Each of the wiring pads 160 may electrically connect a corresponding bonding pad 180 among the bonding pads 180 to a corresponding wiring pattern 142 among the wiring patterns 142. In an embodiment, the bonding pads 180 may include at least one of copper, aluminum, tungsten, nickel, gold, tin, titanium, or an alloy thereof.

The protection layer 170 may be disposed on the wiring layer 140. The protection layer 170 may cover portions of the upper surfaces and side surfaces of the wiring pads 160. The protection layer 170 may not cover remaining portions of the upper surfaces of the wiring pads 160. The protection layer 170 may include an organic dielectric material. In an embodiment, the protection layer 170 may include a photoimageable dielectric (photosensitive dielectric; PID). In an embodiment, the photoimageable dielectric (PID) may include a polyimide-based photosensitive polymer, a novolak-based photosensitive polymer, polybenzoxazole, a silicone-based polymer, an acrylate-based polymer, or an epoxy-based polymer.

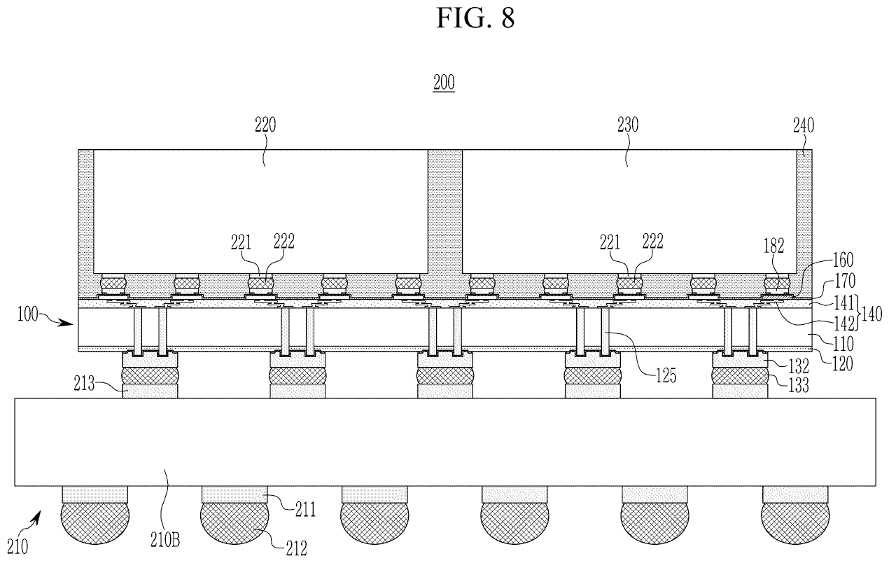

Each of the 180 bonding pads may be disposed on a corresponding wiring pad 160 of the wiring pads 160. Each of the bonding pads 180 may include an under bump metallurgy (UBM) layer 181 and a pad terminal 182. Each of the bonding pads 180 may be electrically connected to a semiconductor die (see the first semiconductor die 220 or the second semiconductor die 230 of FIG. 8).

The under bump metallurgy (UBM) layer 181 may include a diffusion barrier layer and a seed metal layer. The diffusion barrier layer and the seed metal layer may line the space or interposed between the wiring pads 160 and the pad terminal 182, and between the protection layer 170 and the pad terminal 182. The diffusion barrier layer may improve electrical characteristics between the wiring pads 160 and the pad terminal 182. The diffusion barrier layer may act as an adhesion layer. In an embodiment, the diffusion barrier layer may include at least one of a tantalum nitride, a titanium nitride, tantalum, titanium, and an alloy thereof. The seed metal layer may be indistinguishable from the pad terminal 182. For example, the seed metal layer and the pad terminal 182 may be integrally formed as one body without boundaries therebetween. In an embodiment, the seed metal layer may be formed of a copper alloy, or copper including silver, chromium, nickel, tin, gold, and a combination thereof.

The pad terminal 182 may electrically connect a corresponding wiring pad 160 among the wiring pads 160 to a terminal of an external device. In an embodiment, the pad terminal 182 may include at least one of copper, aluminum, tungsten, nickel, gold, tin, titanium, or an alloy thereof.

According to the present disclosure, due to a shape of the through silicon via (TSV) 125 protruding from the second regions R2 (recessed portions) of the passivation layer 120, anchoring between the through silicon via (TSV) 125 and the conductive pillar 132 may be improved, and an area of the under bump metallurgy (UBM) layer 131 interposed between the through silicon via (TSV) 125 and the conductive pillar 132 may be increased. This may improve reliability of the electrical connection between the through silicon via (TSV) 125 and the conductive pillar 132.

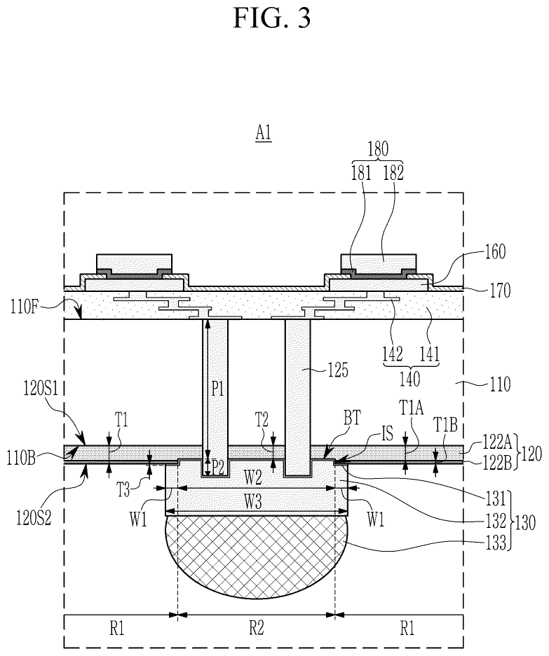

FIG. 3 illustrates a cross-sectional view showing a modified embodiment of the interposer 100 of FIG. 1 and a region A of FIG. 2. In FIG. 3, a transformed region A1 of the region A in FIG. 2 is shown. The region A1 of FIG. 3 is an enlarged view of the region A of FIG. 1 according to the present embodiment. The embodiment illustrated in FIG. 3 shows a different structure from the region A of the embodiment illustrated in FIG. 2.

Referring to FIG. 3, the passivation layer 120 may include an inner passivation layer 122A and an outer passivation layer 122B. The inner passivation layer 122A may be disposed on the back side 110B of the base layer 110. The outer passivation layer 122B may be disposed on the inner passivation layer 122A, and may be exposed to the outside. The recessed portion (second region R2) may include a bottom surface BT and an inner surface IS. The inner surface IS may have a profile perpendicular to the bottom surface BT. In a case where the passivation layer 120 is an inorganic dielectric layer (122A and 122B), dry etching may be performed to create the inner surface IS having a profile perpendicular to the bottom surface BT during a recessing process.

The inner passivation layer 122A and the outer passivation layer 122B may include an inorganic dielectric material. In an embodiment, the inner passivation layer 122A may include a silicon oxide. In an embodiment, the inner passivation layer 122A may include SiO₂. In an embodiment, the outer passivation layer 122A may include a silicon nitride. In an embodiment, the outer passivation layer 122B may include SiN or SiCN. The inner passivation layer 122A may have a fourth thickness T1A in a vertical direction, e.g., from the first surface 120S1 to a bottom surface of the inner passivation layer 122A. In an embodiment, the fourth thickness T1A may be in a range of about 1.5 μm to about 3.5 μm. The outer passivation layer 122B may have a fifth thickness T1B in the vertical direction, e.g., from a contacting surface with the inner passivation layer 122A to a bottom surface of the outer passivation layer 122B. In an embodiment, the fifth thickness T1B may be in a range of about 0.5 μm to about 1.5 μm.

Except for the contents described for the passivation layer 120 of FIG. 3, the contents described for the interposer 100 of FIGS. 1 and 2 may be applied to the present embodiment. For example, features of the interposer 100 of the present embodiment which are not described herein may be the same as the features described above with respect to FIGS. 1 and 2.

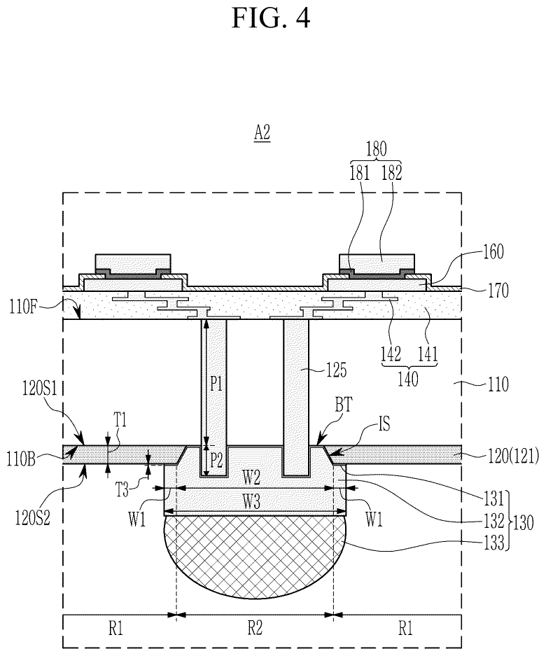

FIG. 4 illustrates a cross-sectional view showing a modified embodiment of the interposer of FIG. 1 and a region A of FIG. 2. In FIG. 4, a transformed region A2 of the region A in FIG. 2 is shown. The region A2 of FIG. 4 is an enlarged view of the region A of FIG. 1 according to the present embodiment. The embodiment illustrated in FIG. 4 shows a different structure from the region A of the embodiment illustrated in FIG. 2.

Referring to FIG. 4, the passivation layer 120 may include a first surface 120S1 contacting the back side 110B of the base layer 110 and a second surface 120S2 opposite to the first surface 120S1. The passivation layer 120 may include a first region R1 and second regions R2. The first region R1 and the second regions R2 may divide the second surface 120S2 of the passivation layer 120. Each of the second regions R2 may be a through opening, e.g., an opening formed in the passivation layer 120 from the first surface 120S1 to the second surface 120S2 of the passivation layer 120. The through opening may include a bottom surface BT and an inner surface IS. The base layer 110 may be extended on the bottom surface BT. For example, the bottom surface BT of the through opening may be the back side 110B of the base layer 110. The inner surface IS may have a profile that is inclined at an angle with respect to the bottom surface BT.

Except for the contents described for the passivation layer 120 of FIG. 4, the contents described for the interposer 100 of FIGS. 1 and 2 may be applied to the present embodiment. For example, features of the interposer 100 of the present embodiment which are not described herein may be the same as the features described above with respect to FIGS. 1 and 2.

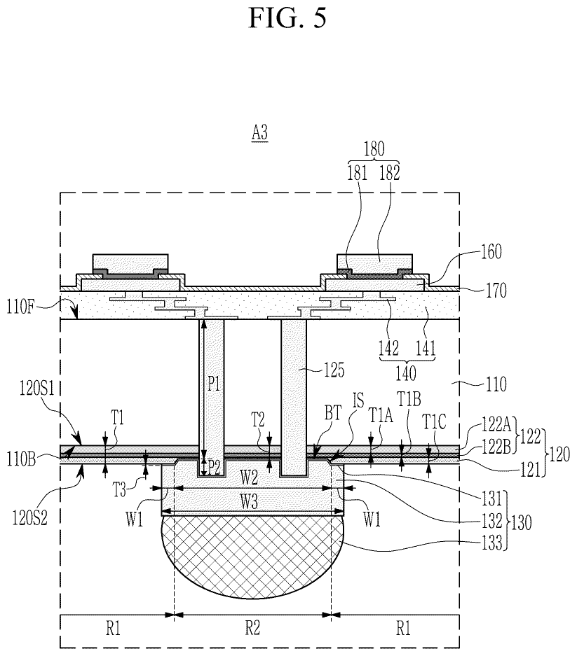

FIG. 5 illustrates a cross-sectional view showing a modified embodiment of the interposer of FIG. 1 and a region A of FIG. 2. In FIG. 5, a transformed region A3 of the region A in FIG. 2 is shown. The region A3 of FIG. 5 is an enlarged view of the region A of FIG. 1 according to the present embodiment. The embodiment illustrated in FIG. 5 shows a different structure from the region A of the embodiment illustrated in FIG. 2.

Referring to FIG. 5, the passivation layer 120 may include a first passivation layer 122 and a second passivation layer 121. The first passivation layer 122 may include a first inner passivation layer 122A and a second inner passivation layer 122B. The first inner passivation layer 122A may be disposed on the back side 110B of the base layer 110. The second inner passivation layer 122B may be disposed on the first inner passivation layer 122A. The second passivation layer 121 may be disposed on the second inner passivation layer 122B of the first passivation layer 122, and may be exposed to the outside.

The passivation layer 120 may include a first surface 120S1 that contacts the back side 110B of the base layer 110 and a second surface 120S2 that is opposite to the first surface 120S1 and includes a recessed portion. The passivation layer 120 may include a first region R1 and second regions R2. The first region R1 and the second regions R2 may divide the second surface 120S2 of the passivation layer 120. The first region R1 may be a non-recessed region. The first region R1 may have a first thickness T1 in a vertical direction, e.g., from the first surface 120S1 to the second surface 120S2. In an embodiment, the first thickness T1 may be in a range of about 3 μm to about 10 μm. The second regions R2 may be regions including recessed portions, e.g., regions vertically overlapping the recessed portions. The second region R2 may have a second thickness T2 in the vertical direction, e.g., from the first surface 120S1 to the second surface 120S2. The second thickness T2 may be smaller than the first thickness T1. In an embodiment, the second thickness T2 may be in a range of about 2.5 μm to about 5.5 μm.

The second passivation layer 121 may include a recessed portion (second region R2). The recessed portion (second region R2) may extend or be formed within the second passivation layer 121. The recessed portion (second region R2) may include a bottom surface BT and an inner surface IS. The second passivation layer 121 may be extended on the bottom surface BT. The inner surface IS may have a profile that is inclined at an angle with respect to the bottom surface BT, e.g., in a cross-sectional view.

The first passivation layer 122 may include an inorganic dielectric material. In an embodiment, the first inner passivation layer 122A may include a silicon oxide. In an embodiment, the first inner passivation layer 122A may include SiO₂. The first inner passivation layer 122A may have a fourth thickness T1A in a vertical direction, e.g., from the first surface 120S1 to a bottom surface of the first inner passivation layer 122A. In an embodiment, the fourth thickness T1A may be in a range of about 1.5 μm to about 3.5 μm. In an embodiment, the second inner passivation layer 122B may include a silicon nitride. In an embodiment, the second inner passivation layer 122B may include SiN or SiCN. The second inner passivation layer 122B may have a fifth thickness T1B in the vertical direction, e.g., from a contacting surface with the inner passivation layer 122A. In an embodiment, the fifth thickness T1B may be in a range of about 0.5 μm to about 1.5 μm.

The second passivation layer 121 may include an organic dielectric material. In an embodiment, the organic dielectric material may include a photoimageable dielectric (photosensitive dielectric; PID). In an embodiment, the photoimageable dielectric (PID) may include a polyimide-based photosensitive polymer, a novolak-based photosensitive polymer, polybenzoxazole, a silicone-based polymer, an acrylate-based polymer, or an epoxy-based polymer. The second passivation layer 121 may have a sixth thickness T1C in a vertical direction, e.g., from a bottom surface to a top surface of the second passivation layer 121. In an embodiment, the sixth thickness T1C may be in a range of about 1 μm to about 5 μm.

Except for the contents described for the passivation layer 120 of FIG. 5, the contents described for the interposer 100 of FIGS. 1 and 2 may be applied to the present embodiment. For example, features of the interposer 100 of the present embodiment which are not described herein may be the same as the features described above with respect to FIGS. 1 and 2.

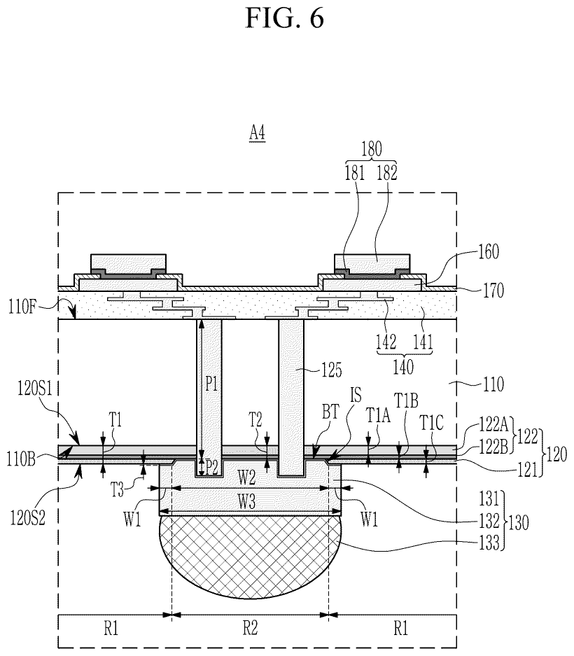

FIG. 6 illustrates a cross-sectional view showing a modified embodiment of the interposer of FIG. 1 and a region A of FIG. 2. In FIG. 6, a transformed region A4 of the region A in FIG. 2 is shown. For example, the embodiment illustrated in FIG. 6 shows region A4 corresponding to region A of FIG. 1. The embodiment illustrated in FIG. 6 shows a different structure from the region A of the embodiment illustrated in FIG. 2.

Referring to FIG. 6, the passivation layer 120 may include a first passivation layer 122 and a second passivation layer 121. The first passivation layer 122 may include a first inner passivation layer 122A and a second inner passivation layer 122B. The first inner passivation layer 122A may be disposed on the back side 110B of the base layer 110. The second inner passivation layer 122B may be disposed on the first inner passivation layer 122A. The second passivation layer 121 may be disposed on the second internal passivation layer 122B of the first passivation layer 122, and may be exposed to the outside.

The passivation layer 120 may include a first surface 120S1 that contacts the back side 110B of the base layer 110 and a second surface 120S2 that is opposite to the first surface 120S1 and includes a recessed portion. The passivation layer 120 may include a first region R1 and second regions R2. The first region R1 and the second regions R2 may divide the second surface 120S2 of the passivation layer 120. The first region R1 may be a non-recessed region. The first region R1 may have a first thickness T1 in a vertical direction, e.g., from the first surface 120S1 to the second surface 120S2. In an embodiment, the first thickness T1 may be in a range of about 3 μm to about 10 μm. The second regions R2 may be regions including or vertically overlapping recessed portions. The second region R2 may have a second thickness T2 in the vertical direction, e.g., from the first surface 120S1 to the second surface 120S2. The second thickness T2 may be smaller than the first thickness T1. In an embodiment, the second thickness T2 may be in a range of about 2 μm to about 5 μm.

The second passivation layer 121 may include a through opening within the second region R2, e.g., an opening formed in the second passivation layer 121 from a top surface to a bottom surface of the second passivation layer 121. The through opening may extend within the second passivation layer 121. The recessed portion (second region R2) may include a bottom surface BT and an inner surface IS. A second inner passivation layer 122B may be extended on the bottom surface BT. The inner surface IS may have a profile that is inclined at an angle with respect to the bottom surface BT, e.g., in a cross-sectional view.

The first passivation layer 122 may include an inorganic dielectric material. In an embodiment, the first inner passivation layer 122A may include a silicon oxide. In an embodiment, the first inner passivation layer 122A may include SiO₂. The first inner passivation layer 122A may have a fourth thickness T1A in a vertical direction, e.g., from the first surface 120S1 to a bottom surface of the first inner passivation layer 122A. In an embodiment, the fourth thickness T1A may be in a range of about 1.5 μm to about 3.5 μm. In an embodiment, the second inner passivation layer 122B may include a silicon nitride. In an embodiment, the second inner passivation layer 122B may include SiN or SiCN. The second inner passivation layer 122B may have a fifth thickness T1B in the vertical direction, e.g., from a contacting surface with the inner passivation layer 122A to a bottom surface of the second inner passivation layer 122B. In an embodiment, the fifth thickness T1B may be in a range of about 0.5 μm to about 1.5 μm.

The second passivation layer 121 may include an organic dielectric material. In an embodiment, the organic dielectric material may include a photoimageable dielectric (photosensitive dielectric; PID). In an embodiment, the photoimageable dielectric (PID) may include a polyimide-based photosensitive polymer, a novolak-based photosensitive polymer, polybenzoxazole, a silicone-based polymer, an acrylate-based polymer, or an epoxy-based polymer. The second passivation layer 121 may have a sixth thickness T1C in a vertical direction, e.g., from an upper surface to a bottom surface of the second passivation layer 121. In an embodiment, the sixth thickness T1C may be in a range of about 1 μm to about 5 μm.

Except for the contents described for the passivation layer 120 of FIG. 6, the contents described for the interposer 100 of FIGS. 1 and 2 may be applied to the present embodiment. For example, features of the interposer 100 of the present embodiment which are not described herein may be the same as the features described above with respect to FIGS. 1 and 2.

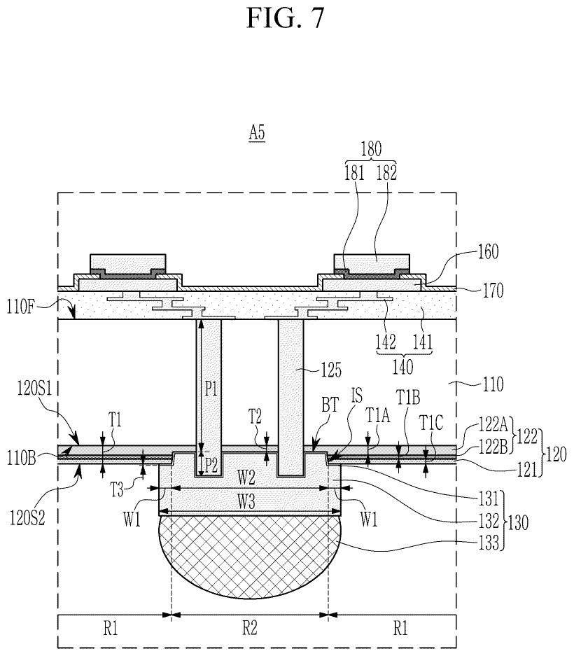

FIG. 7 illustrates a cross-sectional view showing a modified embodiment of the interposer of FIG. 1 and a region A of FIG. 2. In FIG. 7, a transformed region A5 of the region A in FIG. 2 is shown. For example, the embodiment illustrated in FIG. 7 shows region A5 corresponding to region A of FIG. 1. The embodiment illustrated in FIG. 7 shows a different structure from the region A of the embodiment illustrated in FIG. 2.

Referring to FIG. 7, the passivation layer 120 may include a first passivation layer 122 and a second passivation layer 121. The first passivation layer 122 may include a first inner passivation layer 122A and a second inner passivation layer 122B. The first inner passivation layer 122A may be disposed on and/or contact the back side 110B of the base layer 110. The second inner passivation layer 122B may be disposed on and/or contact the first inner passivation layer 122A. The second passivation layer 121 may be disposed on and/or contact the second internal passivation layer 122B of the first passivation layer 122, and may be exposed to the outside.

The passivation layer 120 may include a first surface 120S1 that contacts the back side 110B of the base layer 110 and a second surface 120S2 that is opposite to the first surface 120S1 and includes a recessed portion. The passivation layer 120 may include a first region R1 and second regions R2. The first region R1 and the second regions R2 may divide the second surface 120S2 of the passivation layer 120. The first region R1 may be a non-recessed region. The first region R1 may have a first thickness T1 in a vertical direction, e.g., from the first surface 120S1 to the second surface 120S2. In an embodiment, the first thickness T1 may be in a range of about 3 μm to about 10 μm. The second regions R2 may be regions including and/or vertically overlapping recessed portions. The second region R2 may have a second thickness T2 in the vertical direction, e.g., from the first surface 120S1 to the second surface 120S2. The second thickness T2 may be smaller than the first thickness T1. In an embodiment, the second thickness T2 may be in a range of about 1 μm to about 3.5 μm.

The recessed portion (second region R2) may include a first portion extending, e.g., in a vertical direction, through the second passivation layer 121 and a second portion in which the first passivation layer 122 is recessed. The second inner passivation layer 122B may include a through opening within the second region R2, e.g., an opening formed in the second passivation layer 122B from a bottom surface to a top surface of the second passivation layer 122B. The recessed portion (second region R2) may include a bottom surface BT and an inner surface IS. A first inner passivation layer 122A may be extended on the bottom surface BT. The inner surface IS formed in the first passivation layer 122 may have a profile perpendicular to the bottom surface BT. The inner surface IS formed in the second passivation layer 121 may have a profile that is inclined at an angle with respect to the bottom surface BT.

The first passivation layer 122 may include an inorganic dielectric material. In an embodiment, the first inner passivation layer 122A may include a silicon oxide. In an embodiment, the first inner passivation layer 122A may include SiO₂. The first inner passivation layer 122A may have a fourth thickness T1A in a vertical direction, e.g., from the first surface 120S1 to a bottom surface of the first inner passivation layer 122A. In an embodiment, the fourth thickness T1A may be in a range of about 1.5 μm to about 3.5 μm. In an embodiment, the second inner passivation layer 122B may include a silicon nitride. In an embodiment, the second inner passivation layer 122B may include SiN or SiCN. The second inner passivation layer 122B may have a fifth thickness T1B in the vertical direction, e.g., from a contacting surface with the first inner passivation layer 122A to a bottom surface of the second inner passivation layer 122B. In an embodiment, the fifth thickness T1B may be in a range of about 0.5 μm to about 1.5 μm.

The second passivation layer 121 may include an organic dielectric material. In an embodiment, the organic dielectric material may include a photoimageable dielectric (photosensitive dielectric; PID). In an embodiment, the photoimageable dielectric (PID) may include a polyimide-based photosensitive polymer, a novolak-based photosensitive polymer, polybenzoxazole, a silicone-based polymer, an acrylate-based polymer, or an epoxy-based polymer. The second passivation layer 121 may have a sixth thickness T1C in a vertical direction, e.g., from an upper surface to a bottom surface of the second passivation layer 121. In an embodiment, the sixth thickness T1C may be in a range of about 1 μm to about 5 μm.

Except for the contents described for the passivation layer 120 of FIG. 7, the contents described for the interposer 100 of FIGS. 1 and 2 may be applied to the present embodiment. For example, features of the interposer 100 of the present embodiment which are not described herein may be the same as the features described above with respect to FIGS. 1 and 2.

FIG. 8 illustrates a cross-sectional view showing a semiconductor package 200 including the interposer 100 of FIG. 1.

Referring to FIG. 8, the semiconductor package 200 may include a substrate 210, an interposer 100, a first semiconductor die 220, a second semiconductor die 230, and a molding material 240. In an embodiment, the semiconductor package 200 may be manufactured based on or to be compatible with fan-out wafer level package (FOWLP) or fan-out panel level package (FOPLP) technology.

The substrate 210 may be disposed on a lower surface of the interposer 100, and may be electrically connected to the bump structure 130 of the interposer 100. In an embodiment, the substrate 210 may include a printed circuit board (PCB). The substrate 210 may include a substrate base 210B, conductive pads 211, solders 212, and bonding pads 213. The substrate base 210B may include wiring patterns that can electrically connect the conductive pads 211 and the bonding pads 213 to each other. In an embodiment, the substrate base 210B may include a polymer material. The substrate base 210B may be electrically connected to an external device by the conductive pads 211 and the solders 212. In an embodiment, the conductive pads 211 may include at least one of copper, nickel, zinc, gold, silver, platinum, palladium, chromium, or an alloy thereof. In an embodiment, the solders 212 may include at least one of tin, silver, lead, nickel, copper, or an alloy thereof. The substrate base 210B may be electrically connected to the interposer 100 by the bonding pads 213.

The interposer 100 may route power from the outside to the first semiconductor die 220 and/or the second semiconductor die 230, and/or route a signal from the outside to the first semiconductor die 220 and/or the second semiconductor die 230. The interposer 100 may route signals between the first semiconductor die 220 and the second semiconductor die 230.

The first semiconductor die 220 may be disposed on the interposer 100. The first semiconductor die 220 may be disposed next to the second semiconductor die 230. The first semiconductor die 220 may be electrically connected to the interposer 100 by the conductive pillars 221 and the solders 222. In an embodiment, the first semiconductor die 220 may include a logic die. In an embodiment, the first semiconductor die 220 may include a system on chip (SoC). In an embodiment, the first semiconductor die 220 may include at least one of a central processing unit (CPU) or a graphics processing unit (GPU).

The second semiconductor die 230 may be disposed on the interposer 100. The second semiconductor die 230 may be disposed next to the first semiconductor die 220. The second semiconductor die 230 may be electrically connected to the interposer 100 by the conductive pillars 221 and the solders 222. In an embodiment, the second semiconductor die 230 may include a memory die. In an embodiment, the second semiconductor die 230 may include a DRAM or a high bandwidth memory (HBM). The high bandwidth memory (HBM) may be a high-performance three-dimensional (3D) stacked dynamic random access memory RAM (DRAM). The High-bandwidth memory (HBM) may be manufactured by performing hybrid bonding or by vertically stacking memory dies on a buffer chip using micro bumps to form a single memory stack.

Each of the conductive pillars 221 may be disposed between a corresponding wire among wires of the first semiconductor die 220 or the second semiconductor die 230 and a corresponding solder 222 among the solders 222, and may electrically connect the corresponding solder 222 among the solders 222 to a corresponding wire among wires of the first semiconductor die 220 or the second semiconductor die 230. Each of the solders 222 may be disposed between a corresponding conductive pillar 221 among the conductive pillars 221 and a corresponding bonding pad 180 among the bonding pads 180 of the interposer 100, and may electrically connect a corresponding bonding pad 180 among the bonding pads 180 of the interposer 100 to a corresponding conductive pillar 221 among the conductive pillars 221. In an embodiment, the conductive pillars 221 may include at least one of copper, nickel, zinc, gold, silver, platinum, palladium, chromium, or an alloy thereof. In an embodiment, the solders 222 may include at least one of tin, silver, lead, nickel, copper, or an alloy thereof.

The molding material 240 may cover the first semiconductor die 220 and the second semiconductor die 230 on the interposer 100. An upper surface of the first semiconductor die 220 and an upper surface of the second semiconductor die 230 may be exposed to the outside from the molding material 240. The molding material 240 may protect the first semiconductor die 220 and the second semiconductor die 230 from an external environment, thereby ensuring electrical and mechanical stability of the semiconductor package 200.

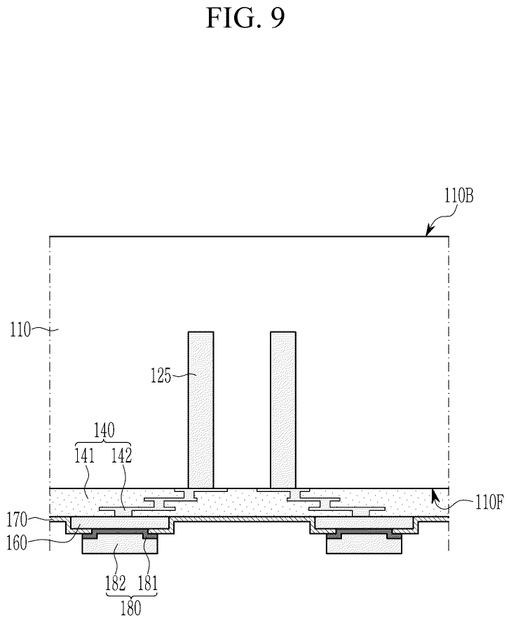

FIG. 9 to FIG. 23 illustrate cross-sectional views for describing a manufacturing method for the interposer 100 of FIG. 1.

FIG. 9 illustrates a cross-sectional view showing an operation of providing the base layer 110.

Referring to FIG. 9, the base layer 110 may be provided. The base layer 110 may have a wiring layer 140, a wiring pad 160, a protection layer 170, and a bonding pad 180 disposed on the front side 110F. The through silicon vias 125 electrically connected to and/or contacting the wiring layer 140 and extending vertically from the front side 110F of the base layer 110 toward the back side 110B may be included within the base layer 110.

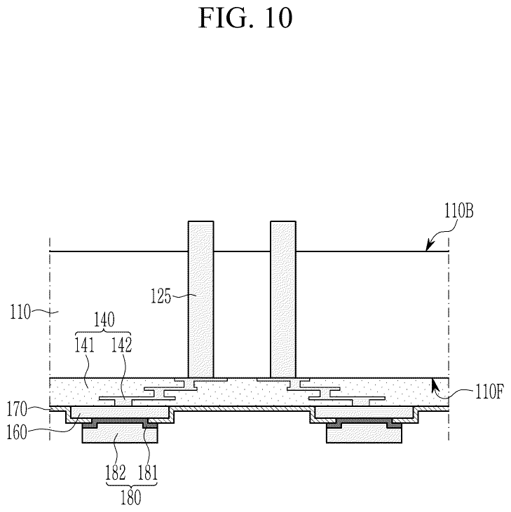

FIG. 10 illustrates a cross-sectional view showing an operation of exposing the through silicon vias 125 on the back side 110B of the base layer 110.

Referring to FIG. 10, the back side 110B of the base layer 110 may be thinned/removed. In an embodiment, the back side 110B of the base layer 110 may be thinned by performing grinding. Thereafter, wet etching may be performed from the back side 110B of the base layer 110 to expose the through silicon vias 125 to the outside. When wet etching is performed on the base layer 110, a barrier layer around an exposed surface of each of the through silicon vias 125 among the through silicon vias 125 may be removed together.

According to the present disclosure, the protruding through silicon via 125 may be easily measured/detected, and by using the easily measurable protruding through silicon via 125 as an alignment key, subsequent photolithography processes may be performed without error.

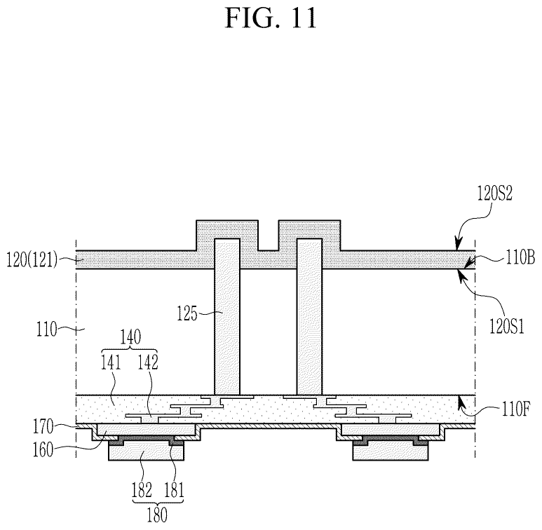

FIG. 11 illustrates a cross-sectional view showing an operation of forming the passivation layer 120 on the back side 110B of the base layer 110.

Referring to FIG. 11, the passivation layer 120 may be formed continuously and conformally along the back side 110B of the etched base layer 110 and along surfaces of the exposed through silicon vias 125. In an embodiment, the passivation layer 120 may be formed by performing an atomic layer deposition (ALD) process or a chemical vapor deposition (CVD) process.

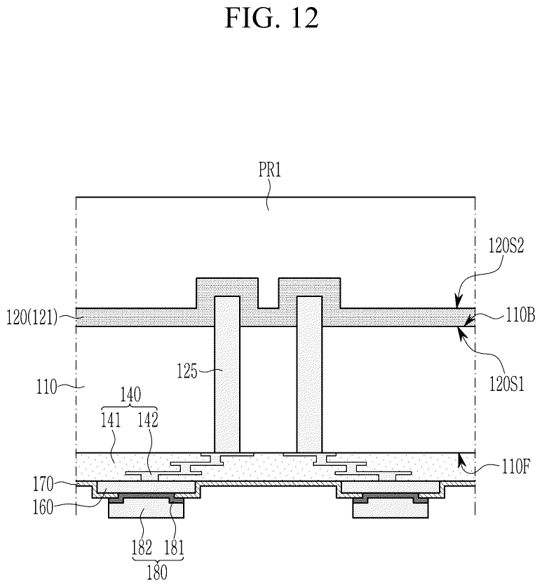

FIG. 12 illustrates a cross-sectional view showing an operation of forming the first photoresist layer PR1 on the passivation layer 120.

Referring to FIG. 12, the first photoresist layer PR1 may be applied on the passivation layer 120. In an embodiment, the first photoresist layer PR1 may be formed through a spin coating process. In an embodiment, the first photoresist layer PR1 may include an organic polymer resin containing a photoactive material.

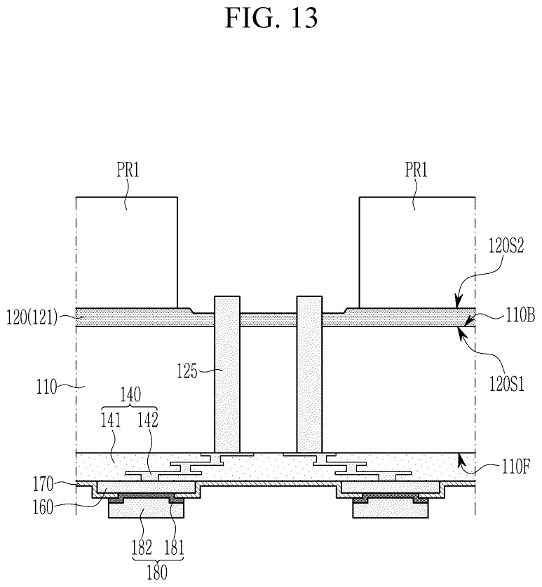

FIG. 13 illustrates a cross-sectional view showing an operation of forming a pattern of the first photoresist layer PR1 and forming a recessed portion in the passivation layer 120.

Referring to FIG. 13, the first photoresist layer PR1 is exposed and developed to form a pattern of the first photoresist layer PR1. The formed pattern of the first photoresist layer PR1 may function as a photomask, and only a portion of the passivation layer 120 may be exposed and developed by the pattern of the first photoresist layer PR1, and a recessed portion may be formed in the passivation layer 120. The through silicon vias 125 may be exposed on the recessed portion of the passivation layer 120. In certain embodiments, the pattern of the first photoresist layer PR1 may function as an etching mask, and the exposed portion of the passivation layer 120 may be partially removed by a dry etching process or a wet etching process to form the recess shown in FIG. 13.

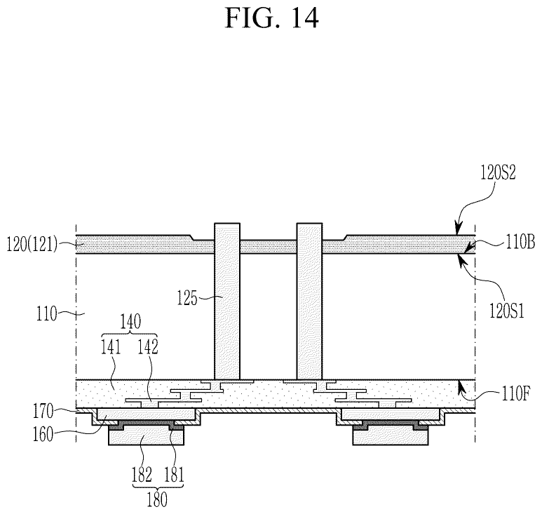

FIG. 14 illustrates a cross-sectional view showing an operation of removing the pattern of the first photoresist layer PR1.

Referring to FIG. 14, the pattern of the first photoresist layer PR1 may be removed. In an embodiment, the pattern of the first photoresist layer PR1 may be removed by performing at least one of an etching process, an ashing process, and/or a strip process.

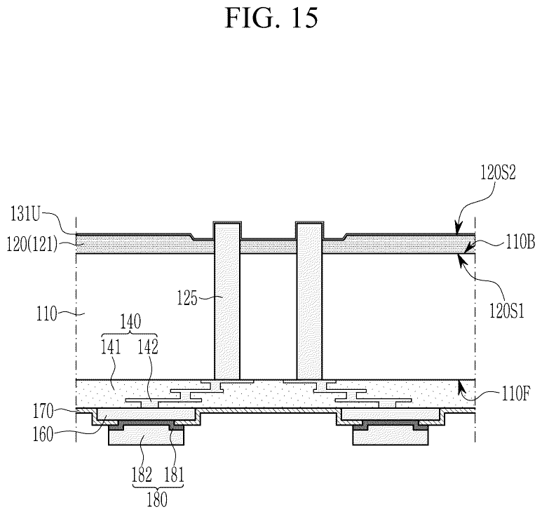

FIG. 15 illustrates a cross-sectional view showing an operation of forming a diffusion barrier layer 131U among the under bump metallurgy (UBM) layers 131.

Referring to FIG. 15, the diffusion barrier layer 131U may be formed continuously and conformally along the passivation layer 120 and along surfaces of the exposed through silicon vias 125. In an embodiment, the diffusion barrier layer 131U may be formed by performing a sputtering process.

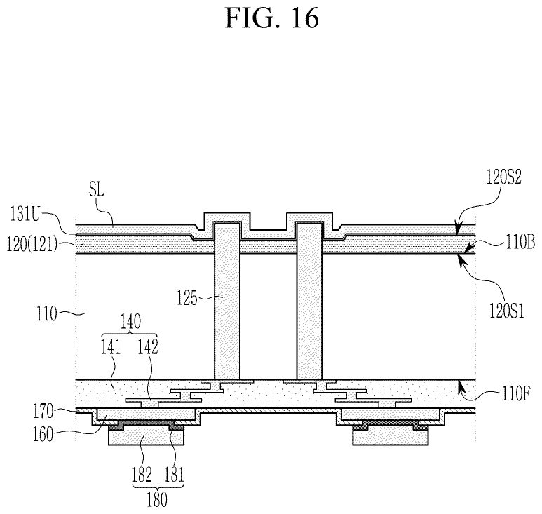

FIG. 16 illustrates a cross-sectional view showing an operation of forming a seed metal layer SL on the diffusion barrier layer 131U.

Referring to FIG. 16, the seed metal layer SL may be disposed on the diffusion barrier layer 131U. The seed metal layer SL may be formed continuously and conformally along the diffusion barrier layer 131U. In an embodiment, the seed metal layer SL may be formed by performing a sputtering process or an electroless plating process.

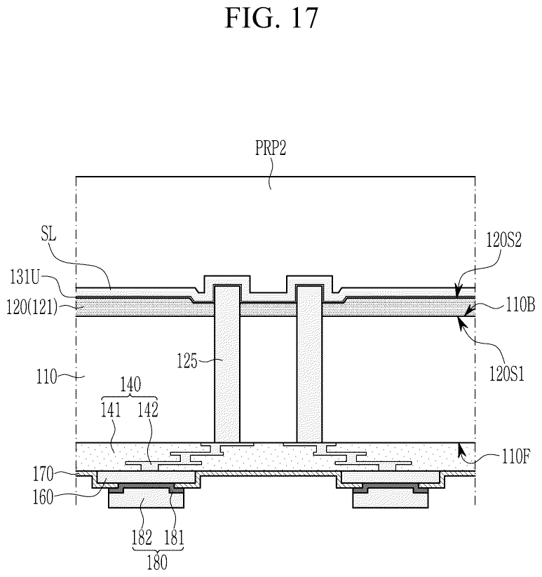

FIG. 17 illustrates a cross-sectional view showing an operation of forming a second photoresist layer PR2 on the seed metal layer SL.

Referring to FIG. 17, the second photoresist layer PR2 may be applied on the seed metal layer SL. In an embodiment, the second photoresist layer PR2 may be formed through a spin coating process. In an embodiment, the second photoresist layer PR2 may include an organic polymer resin containing a photoactive material.

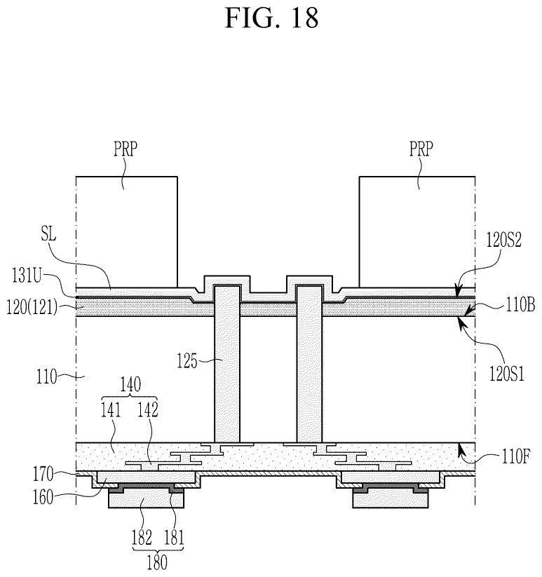

FIG. 18 illustrates a cross-sectional view showing an operation of forming a pattern of the second photoresist layer PR2.

Referring to FIG. 18, the second photoresist layer PR2 is exposed and developed to form the pattern of the second photoresist layer PR2. The seed metal layer SL may be exposed through the pattern of the second photoresist layer PR2.

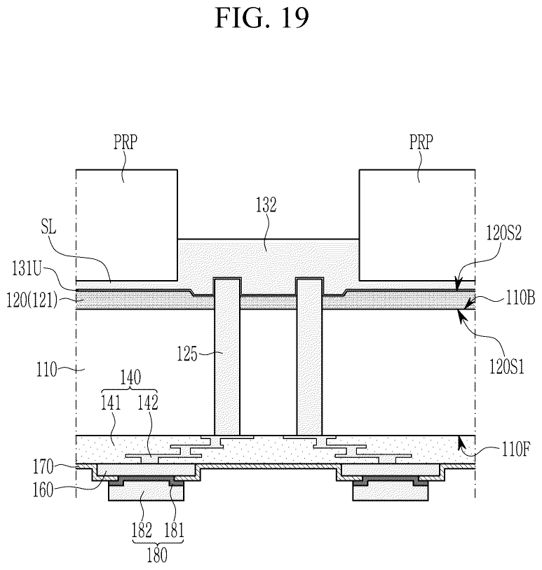

FIG. 19 illustrates a cross-sectional view showing an operation of forming the conductive pillar 132.

Referring to FIG. 19, the conductive pillar 132 may be formed by growing a metal layer by electrolytic plating (electroplating) from the seed metal layer SL formed first.

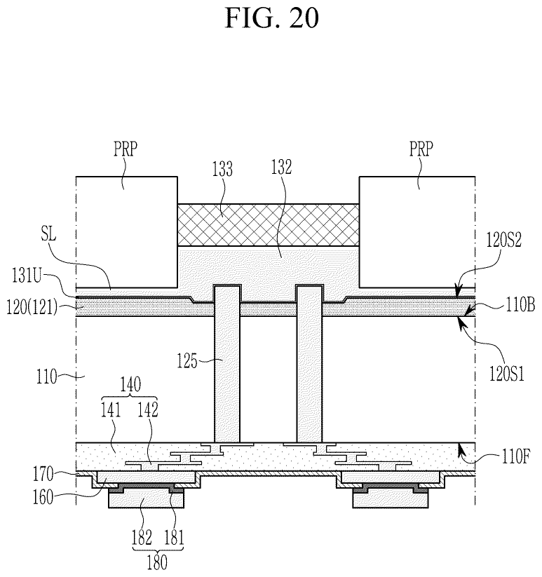

FIG. 20 illustrates a cross-sectional view showing an operation of forming the solder 133.

Referring to FIG. 20, a metal layer may be grown by electrolytic plating to form the solder 133.

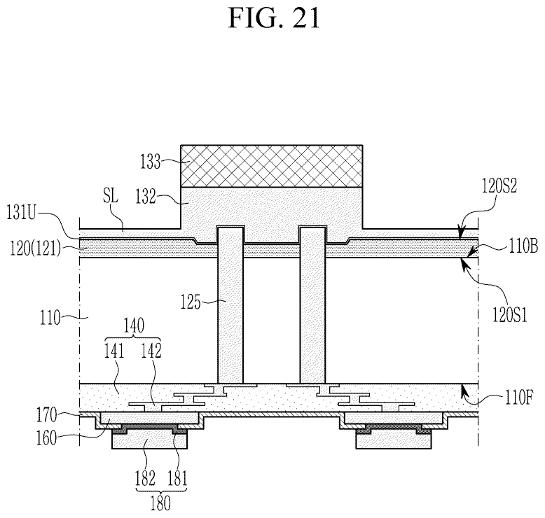

FIG. 21 illustrates a cross-sectional view showing an operation of removing the pattern of the second photoresist layer PR2.

Referring to FIG. 21, the pattern of the second photoresist layer PR2 may be removed. In an embodiment, the pattern of the second photoresist layer PR2 may be removed by performing at least one of an etching process, an ashing process, and/or a strip process.

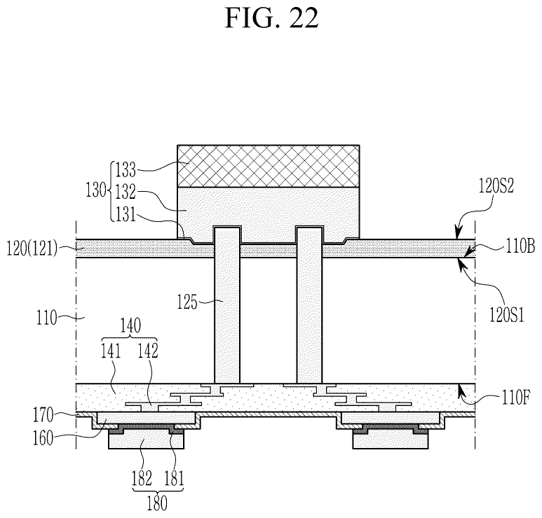

FIG. 22 illustrates a cross-sectional view showing an operation of removing the seed metal layer SL and the diffusion barrier layer 131U.

Referring to FIG. 22, the seed metal layer SL and diffusion barrier layer 131U exposed and not covered by the conductive pillar 132 may be removed. In an embodiment, the seed metal layer SL and the diffusion barrier layer 131U be removed by an etching process.

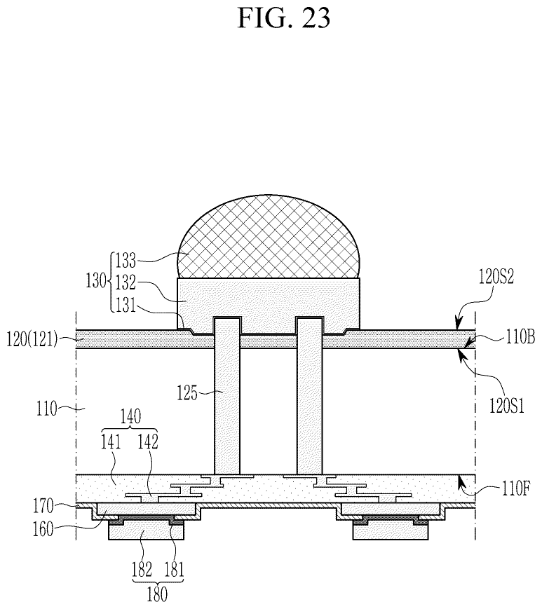

FIG. 23 illustrates a cross-sectional view showing an operation of reflowing the solder 133.

Referring to FIG. 23, by performing a reflow process, the solder 133 may be formed into a spherical shape.

Even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

While this disclosure has been described in connection with what is presently considered to be practical embodiments, it is to be understood that the invention is not limited to the disclosed embodiments, but, on the contrary, is intended to cover various modifications and equivalent arrangements included within the spirit and scope of the appended claims.

What is claimed is:

1. An interposer comprising:
a base layer including a front side and a back side which is opposite to the front side;
a wiring layer on the front side;
a passivation layer on the back side, the passivation layer including a first surface contacting the back side and a second surface opposite to the first surface, the second surface including a recessed portion;
one or more through silicon vias electrically connected to the wiring layer, the one or more through silicon vias extending through the base layer and the passivation layer, the one or more through silicon vias protruding from the recessed portion; and
a conductive pillar disposed on the recessed portion and covering a surface of the one or more through silicon vias.

2. The interposer of claim 1, further comprising
an under bump metallurgy (UBM) layer interposed between the conductive pillar and the recessed portion, and between the conductive pillar and the surface of one or more through silicon vias.

3. The interposer of claim 2, wherein
the under bump metallurgy (UBM) layer conformally extends along between the conductive pillar and the recessed portion, and between the conductive pillar and the surface of one or more through silicon vias.

4. The interposer of claim 1, wherein
the number of the one or more through silicon vias is 1, 2, 4, or 6.

5. The interposer of claim 1, wherein
the passivation layer includes an organic dielectric material.

6. The interposer of claim 5, wherein
the recessed portion includes
a bottom surface; and
an inner surface having a profile that is inclined at an angle with respect to the bottom surface.

7. The interposer of claim 1, wherein
the passivation layer includes an inorganic dielectric material.

8. The interposer of claim 7, wherein
the recessed portion includes
a bottom surface; and
an inner surface having a profile perpendicular to the bottom surface.

9. The interposer of claim 1, wherein
the passivation layer includes
a first passivation layer including an inorganic dielectric material; and
a second passivation layer disposed on the first passivation layer and including an organic dielectric material.

10. The interposer of claim 9, wherein the second passivation layer includes the recessed portion.

11. The interposer of claim 9, wherein
the recessed portion includes a first portion extending through the second passivation layer.

12. The interposer of claim 11, wherein
the recessed portion includes a second portion in which the first passivation layer is recessed.

13. The interposer of claim 1, wherein
the conductive pillar covers the recessed portion and a portion of the second surface around the recessed portion.

14. An interposer comprising:
a base layer including a front side and a back side which is opposite to the front side;
a wiring layer on the front side;
a passivation layer on the back side, the passivation layer including a first surface contacting the back side and a second surface opposite to the first surface, the second surface including a first region having a first thickness in a direction perpendicular to the first surface and a plurality of second regions having a second thickness in a direction perpendicular to the first surface, the second thickness being less than the first thickness;
a plurality of through silicon vias electrically connected to the wiring layer; and
a plurality of conductive pillars on the second surface of the passivation layer,
wherein each of the plurality of through silicon vias includes:
a first portion extending through the base layer and a corresponding second region among the plurality of second regions; and
a second portion protruding from the corresponding second region, and
wherein each conductive pillar of the plurality of conductive pillars covers the second portion of a corresponding through silicon via of the plurality of through silicon vias.

15. The interposer of claim 14, wherein
the second portion of each of the plurality of through silicon vias is surrounded by a corresponding conductive pillar among the plurality of conductive pillars.

16. The interposer of claim 14, wherein
a height of the second portion of each of the plurality of through silicon vias in a vertical direction is greater than or equal to a difference between the first thickness and the second thickness.

17. The interposer of claim 14, wherein
a width of each second region among the plurality of second regions in a horizontal direction is smaller than a width of a corresponding conductive pillar among the plurality of conductive pillars in the horizontal direction.

18. The interposer of claim 14, wherein
each of the second regions among the plurality of second regions is a through opening.

19. A semiconductor package comprising:
a substrate; and
an interposer on the substrate;
a logic die on the interposer; and
a memory die on the interposer and next to the logic die,
wherein the interposer includes:
a base layer including a front side and a back side which is opposite to the front side;
a wiring layer on the front side;
a plurality of bonding pads disposed on the wiring layer, each bonding pad electrically connected to the logic die or the memory die;
a passivation layer disposed on the back side and including a first surface contacting the back side, and a second surface opposite to the first surface and including a plurality of recessed portions;
a plurality of through silicon vias electrically connected to the wiring layer, the plurality of through silicon vias extending through the base layer and the passivation layer, the plurality of through silicon vias protruding from the recessed portions; and
a plurality of conductive pillars, each of the plurality of conductive pillars disposed on a corresponding recessed portion among the recessed portions, each of the plurality of conductive pillars covering a protruding surface of a corresponding through-silicon via among the plurality of through silicon vias.

20. The semiconductor package of claim 19, wherein
the interposer further includes a plurality of solders, and
each solder of the plurality of solders is connected to a corresponding conductive pillar among the plurality of conductive pillars.
